(19) United States
(12) Patent Application Publication
(10) Pub. No.: US 2020/0117391 A1
(43) Pub. Date: Apr. 16, 2020

(54) MEMORY DEVICE AND OPERATING METHOD THEREOF

(71) Applicant: SK hynix Inc., Gyeonggi-do (KR)

(72) Inventor: Tai Kyu KANG, Gyeonggi-do (KR)

(21) Appl. No.: 16/423,660

(22) Filed: May 28, 2019

(30) Foreign Application Priority Data
Oct. 15, 2018 (KR) 10-2018-0122855

(51) Int. Cl. G06F 3/06; G11C 16/30; G11C 16/08

(52) U.S. Cl. CPC G06F 3/0659; G06F 3/0604; G11C 16/08; G11C 16/30; G06F 3/0679

(57) ABSTRACT

A memory device includes a command encoder encoding a command into a command code, a command decoder decoding the command code, selecting one of a plurality of read only memory (ROM) lines according to a decoding result, and outputting an enable signal through a selected ROM line among the plurality of ROM lines, a ROM code generator including a plurality of registers storing ROM codes for executing various operations and outputting a ROM code stored in a register to which the enable signal is input, among the plurality of registers, and an operation controller executing an algorithm according to the ROM code output from the ROM code generator.

### CROSS-REFERENCE TO RELATED APPLICATION

The present application claims priority under 35 U.S.C. § 119(a) to Korean patent application number 10-2018-0122855, filed on Oct. 15, 2018, which is incorporated herein by reference in its entirety.

### BACKGROUND

### Field of Invention

Various embodiments relate generally to a memory device and an operating method thereof, and more particularly, a memory device directly outputting a ROM code according to a command received from a memory controller, and an operating method thereof.

### Description of Related Art

A memory system may include a memory controller and a memory device.

The memory controller may control data communication between a host and the memory system as a storage device. When the memory device is composed of a flash memory device which is a type of non-volatile memory, the memory controller may include a flash transition layer for communication between the memory device and the host.

The host may communicate with the memory device by using an interface protocol such as Peripheral Component Interconnect-Express (PCI-e or PCIe), Advanced Technology Attachment (ATA), Serial ATA (SATA), Parallel ATA (PATA), or serial attached SCSI (SAS). However, the interface protocols provided for the purpose of data communication between the host and the memory system may not be limited to the above examples and may include various other interface protocols such as a Universal Serial Bus (USB), a Multi-Media Card (MMC), an Enhanced Small Disk Interface (ESDI), or Integrated Drive Electronics (IDE).

A memory device may store data or output the stored data. For example, the memory device may include a volatile memory device losing stored data when a power supply is blocked, or a non-volatile memory device retaining the stored data even when the power supply is blocked.

The memory device may store various read only memory (ROM) codes for performing various operations. When receiving a command from the memory controller, the memory device may perform an operation according to a ROM code corresponding to the received command by sequentially searching the stored ROM codes. For example, the memory device may search the stored ROM codes to identify whether the received command corresponds to the first ROM code. When the received command does not correspond to the first ROM code, the memory device may search the ROM codes to identify whether the next ROM code corresponds to the received command. When the ROM codes are sequentially searched in this manner, a time to search the ROM codes may be increased.

### SUMMARY

Various embodiments of the present disclosure provide a memory device capable of shortening a time to start an operation corresponding to a command received from a memory controller by directly outputting a ROM code by decoding the received command, and an operating method thereof.

In accordance with an embodiment, a memory device may include a command encoder encoding a command into a command code, a command decoder decoding the command code, selecting one of a plurality of read only memory (ROM) lines according to a decoding result, and outputting an enable signal through a selected ROM line among the plurality of ROM lines, a ROM code generator including a plurality of registers storing ROM codes for executing various operations and outputting a ROM code stored in a register to which the enable signal is input, among the plurality of registers, and an operation controller executing an algorithm according to the ROM code output from the ROM code generator.

In accordance with an embodiment, a method of operating a memory controller may include receiving a command in response to a request of a host; encoding the command into a command code comprising a plurality of bits; outputting an enable signal to a read only memory (ROM) line mapped to the command code; outputting a ROM code stored in a register to which the enable signal is input, among a plurality of registers; and executing an algorithm according to the ROM code.

In accordance with an embodiment, a memory device may include a command encoder suitable for encoding a command into a command code, a plurality of lines, a command decoder coupled between the command encoder and the plurality of lines, suitable for decoding the command code to output the decoded code as an enable signal for enabling one among the plurality of lines, a code generator including a plurality of registers respectively coupled to the plurality of lines, which stores a plurality of read only memory (ROM) codes, one register selected from among the plurality of registers suitable for generating a corresponding ROM code, among the plurality of ROM codes, in response to the enable signal, and an operation controller suitable for executing an algorithm based on the corresponding ROM code.

### BRIEF DESCRIPTION OF THE DRAWINGS

FIG. 1 is a diagram illustrating a memory system in accordance with an embodiment of the present disclosure;

FIG. 2 is a diagram illustrating a memory controller in accordance with an embodiment of the present disclosure;

FIG. 3 is a diagram illustrating a channel coupling a memory controller and a memory device;

FIG. 4 is a diagram illustrating a memory device in accordance with an embodiment of the present disclosure;

FIG. 5 is a diagram illustrating a control logic in accordance with an embodiment of the present disclosure;

FIG. 6 is a diagram illustrating a ROM table stored in a command decoder;

FIG. 7 is a diagram illustrating a ROM included in a ROM code generator;

FIG. 8 is a diagram illustrating comparative examples of output times of ROM codes in accordance with;

FIG. 9 is a diagram illustrating a memory system in accordance with an embodiment of the present disclosure;

FIG. 10 is a diagram illustrating a memory system in accordance with an embodiment of the present disclosure;

FIG. 11 is a diagram illustrating a memory system in accordance with an embodiment of the present disclosure; and

FIG. 12 is a diagram illustrating a memory system in accordance with an embodiment of the present disclosure.

### DETAILED DESCRIPTION

Hereinafter, specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

It will be understood that when an element is referred to as being “connected” or “coupled” to another element, it can be directly connected or coupled to the other element or intervening elements may also be present. In contrast, when an element is referred to as being “directly connected” or “directly coupled” to another element, no intervening elements are present. Meanwhile, other expressions describing relationships between components such as “between,” “directly between” or “adjacent to” and “directly adjacent to” may be construed similarly.

FIG. 1 is a diagram illustrating a memory system 1000 in accordance with an embodiment of the present disclosure.

Referring to FIG. 1, the memory system 1000 may include a memory device 1100 storing data, a memory controller 1200 and a buffer memory 1300. The buffer memory 1300 may temporarily store data necessary for operations of the memory system 1000. The memory controller 1200 may control the memory device 1100 and the buffer memory 1300 in response to control of a host 2000.

The host 2000 may communicate with the memory system 1000 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Non-volatile Memory express (NVMe), Universal Flash Storage (UFS), Secure Digital (SD), Multi-Media Card (MMC), embedded MMC (eMMC), Dual In-line Memory Module (DIMM), Registered DIMM (RDIMM), and Load Reduced DIMM (LRDIMM) communication methods.

The memory device 1100 may be a volatile memory device losing stored data when power supply is blocked, or a non-volatile memory device retaining the stored data even in the absence of power supply. In this embodiment, a flash memory device, which is a type of non-volatile memory device, will be described as an example.

The memory controller 1200 may control the general operations of the memory system 1000 and control data exchange between the host 2000 and the memory device 1100. The memory controller 1200 may be coupled to the memory device 1100 through a channel CH and transfer commands, addresses, and data through the channel CH. For example, the memory controller 1200 may transfer a command for performing a program, read, or erase operation to the memory device 1100 through the channel CH in response to a request from the host 2000.

For example, when the memory controller 1200 generates a command in response to the request from the host 2000 and transfers the generated command to the memory device 1100 through the channel CH, the memory device 1100 may perform an operation corresponding to the command. Thus, the memory device 1100 may store ROM codes therein corresponding to various operations, respectively, and perform a selected operation by using a ROM code corresponding to the received command. In an embodiment, the memory device 1100 may directly select a ROM code by decoding the received command, whereby an operation corresponding to the command may start quickly. This will be described below in detail.

As shown in FIG. 1, the buffer memory 1300 may be disposed outside the memory controller 1200. However, depending on the structure of the memory system 1000, the buffer memory 1300 may be disposed inside the memory controller 1200. The buffer memory 1300 may serve as an operation memory or a cache memory of the memory controller 1200. The buffer memory 1300 may temporarily store logical information (e.g., a logical address) received from the host 2000 and physical information (e.g., a physical address) of the memory device 1100. In accordance with an embodiment, the buffer memory 1300 may include Double Data Rate Synchronous Dynamic Random Access Memory (DDR SDRAM), DDR4 SDRAM, Low Power Double Data 4 (LPDDR4) SDRAM, Graphics Double Data Rate (GDDR) SDRAM, Low Power DDR (LPDDR), or Rambus Dynamic Random Access Memory (RDRAM).

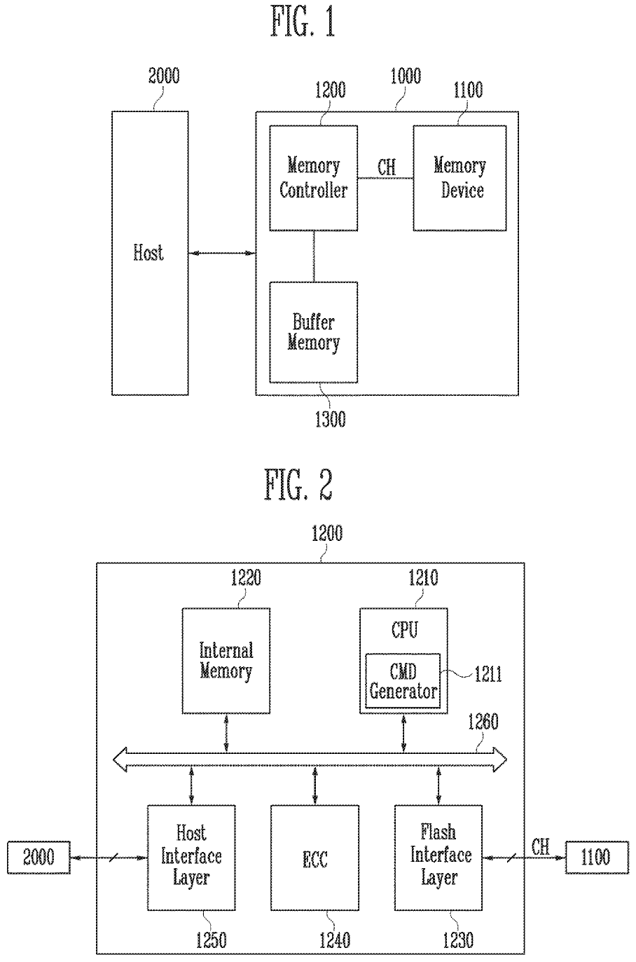

FIG. 2 is a diagram illustrating a memory controller (e.g., the memory controller 1200 of FIG. 1) in accordance with an embodiment of the present disclosure.

Referring to FIG. 2, the memory controller 1200 may include a central processing unit (CPU) 1210, an internal memory 1220, a flash interface layer 1230, an error correction circuit (ECC) 1240, and a host interface layer 1250. The host interface layer 1250 may provide communication between the host 2000 and the memory device 1100. The central processing unit 1210, the internal memory 1220, the flash interface layer 1230, the error correction circuit 1240, and the host interface layer 1250 may communicate with each other through a bus 1260.

When the central processing unit 1210 receives a request from the host 2000 through the host interface layer 1250, the central processing unit 1210 may generate a command for carrying out the received request. The central processing unit 1210 may include a command (CMD) generator 1211. The CMD generator 1211 may generate and output a command CMD corresponding to the request received from the host 2000.

The internal memory 1220 may store various types of system information for operations of the memory controller 1200. For example, the internal memory 1220 may include a static random access memory (SRAM). The internal memory 1220 may store address mapping information for operations of the memory system 1000.

The flash interface layer 1230 may communicate with the memory device 1100 in response to control of the central processing unit 1210. For example, the flash interface layer 1230 may receive commands from the central processing unit 1210, queue the commands therein according to a status of the memory device 1100, and output the commands to the memory device 1100 through the channel CH according to the queued order.

The error correction circuit 1240 may perform an error correction operation under the control of the central processing unit 1210.

The host interface layer 1250 may be configured to communicate with the host 2000 coupled to the memory system 1000 under the control of the central processing unit 1210. For example, the host interface layer 1250 may receive various requests such as a program request, a read request and an erase request from the host 2000, and may output data read from the memory device 1100 to the host 2000.

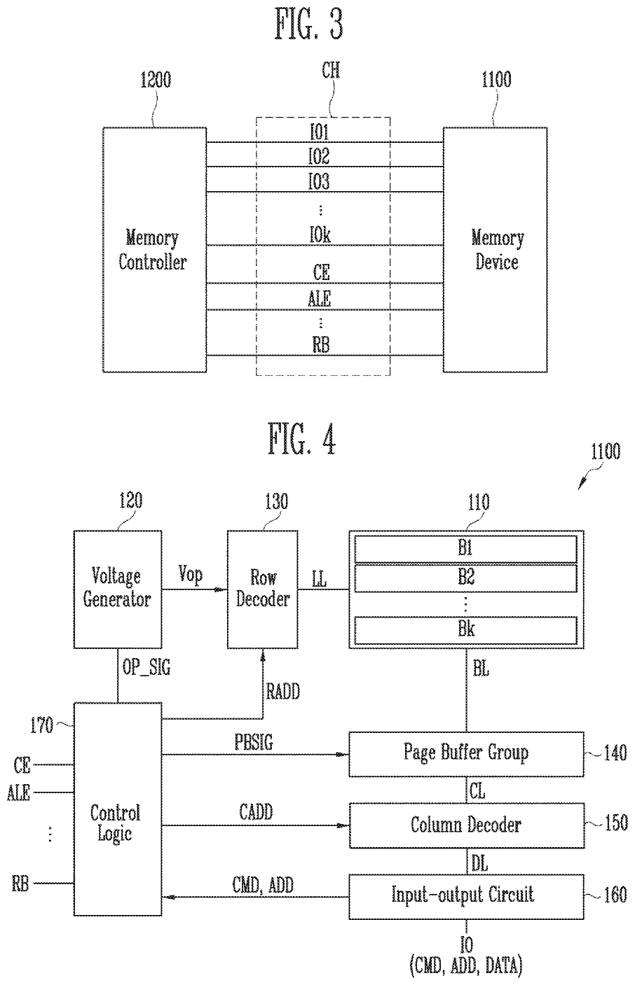

FIG. 3 is a diagram illustrating the channel CH coupling the memory controller 1200 and the memory device 1100.

Referring to FIG. 3, the memory controller 1200 and the memory device 1100 may exchange commands, addresses, and data through the channel CH. For example, the memory controller 1200 may transfer commands, addresses, and data to the memory device 1100 through the channel CH, and the memory device 1100 may transfer data to the memory controller 1200 through the channel CH.

The channel CH may include a plurality of input and output (input/output) lines IO1 to IOk (where k is a positive integer) and a plurality of control lines. For example, the commands, the addresses, and the data may be transferred through the input/output lines IO1 to IOk, and a chip enable signal CE, an address latch enable signal ALE, and a ready/busy signal RB may be transferred through the control lines. When there are a plurality of memory devices 1100, the chip enable signal CE may be transferred for selecting one of the memory devices 1100. The address latch enable signal ALE may be for inputting the addresses loaded onto the input/output lines IO1 to IOk to the memory device 1100. The ready/busy signal RB may indicate that the memory device 1100 is operating, i.e., ready or busy. The chip enable signal CE and the address latch enable signal ALE may be transferred from the memory controller 1200 to the memory device 1100. The ready/busy signal RB may be transferred from the memory device 1100 to the memory controller 1200. In addition to the above-described signals, various other signals may be transferred through the control lines. However, since the control lines are not largely related with this embodiment, a detailed description thereof will be omitted.

FIG. 4 is a diagram illustrating a memory device (e.g., the memory device 1100 of FIG. 1) in accordance with an embodiment of the present disclosure.

Referring to FIG. 4, the memory device 1100 may include a memory cell array 110 storing data, a peripheral circuit configured to perform a program, read, or erase operation, and a control logic 170 controlling the peripheral circuit. The peripheral circuit may include a voltage generator 120, a row decoder 130, a page buffer group 140, a column decoder 150, and an input and output (input-output) circuit 160.

The memory cell array 110 may include a plurality of memory blocks B1 to Bk, where k is a positive integer. The number of memory blocks B1 to Bk and the number of input/output lines IO1 to IOk may not be related to each other. The memory blocks B1 to Bk may include a plurality of memory cells and may have a two-dimensional (2D) or three-dimensional (3) structure. For example, in the 2D structured memory blocks B1 to Bk, the memory cells may be arranged in a horizontal direction to a substrate. In the 3D structured memory blocks B1 to Bk, the memory cells may be stacked in a perpendicular direction to the substrate.

The voltage generator 120 may generate and output operating voltages Vop for respective operations in response to operating signals OP_SIG. For example, the voltage generator 120 may generate a program voltage, a pass voltage, and a program verify voltage when the operating signals OP_SIG are related to a program operation. When the operating signals OP_SIG are related to a read operation, the voltage generator 120 may generate a read voltage and a pass voltage. The voltage generator 120 may generate an erase voltage, a pass voltage, and an erase verify voltage when the operating signals OP_SIG are related to an erase operation.

The row decoder 130 may transfer the operating voltages Vop to a selected memory block among the plurality of memory blocks B1 to Bk through local lines LL in response to a row address RADD.

The page buffer group 140 may be coupled to the memory blocks B1 to Bk through bit lines BL and include a plurality of page buffer groups coupled to the bit lines BL, respectively. The page buffer group 140 may control voltages of the bit lines BL, or may sense voltages or currents in the bit lines BL in response to page control signals PBSIG.

The column decoder 150 may exchange data with the page buffer group 140 through column lines CL, or with the input-output circuit 160 through data lines DL in response to a column address CADD.

The input-output circuit 160 may communicate with the memory controller 1200 of FIGS. 1 and 2 through input/output lines IO. For example, the input-output circuit 160 may transfer the command CMD and an address ADD, received through the input/output lines IO, to the control logic 170, and may transfer received data DATA to the column decoder 150. In addition, the input-output circuit 160 may output the data DATA read from the memory blocks B1 to Bk to the memory controller 1200 through the input/output lines IO.

The control logic 170 may output the operating signals OP_SIG and the page control signals PBSIG in response to the command CMD and may output the row address RADD and the column address CADD in response to the address ADD. For example, when receiving the command CMD, the control logic 170 may select a read only memory (ROM) line corresponding to the received command CMD and output the operating signals OP_SIG and the page control signals PBSIG in response to a ROM code corresponding to the selected ROM line.

In addition, the control logic 170 may receive the command CMD, and the address ADD through the input-output circuit 160 in response to the chip enable signal CE and the address latch enable signal ALE. In addition, the control logic 170 may output the ready/busy signal RB when performing an operation corresponding to the received command CMD.

A method of performing an operation corresponding to the command CMD, among the functions of the above-described control logic 170, is described below in detail.

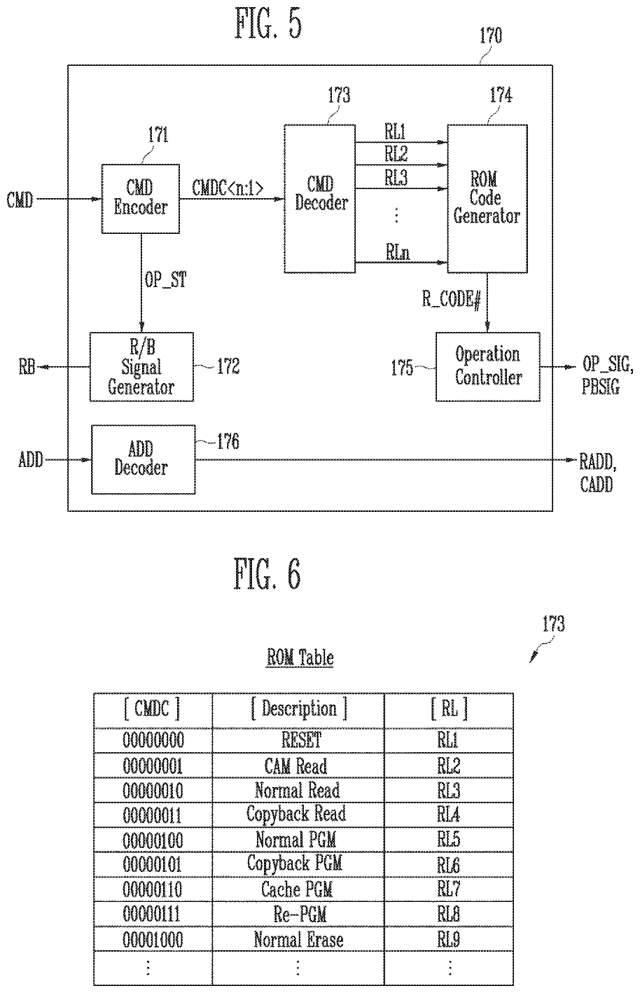

FIG. 5 is a diagram illustrating a control logic (e.g., the control logic 170 of FIG. 4) in accordance with an embodiment of the present disclosure.

Referring to FIG. 5, the control logic 170 may include a command (CMD) encoder 171, a ready/busy (R/B) signal generator 172, a CMD decoder 173, a ROM code generator 174, an operation controller 175, and an ADD decoder 176.

When the CMD encoder 171 receives the command CMD from the memory controller 1200, the CMD encoder 171 may output a command code CMDC<n:1> and an operation start signal OP_ST. For example, the CMD encoder 171 may encode the received command CMD to output the command code CMDC<n:1>. The command code CMDC<n:1> may include a plurality of bits. The bits of the command code CMDC<n:1> may vary depending on the memory device 1100. When the command CMD is received, the operation start signal OP_ST may transition from a logic high level to a logic low level, and a logic low or high level signal may be set depending on the memory device 1100. The order in which the command code CMDC<n:1> and the operation start signal OP_ST are output may be changed, or the command code CMDC<n:1> and the operation start signal OP_ST may be output at the same time.

When the operation start signal OP_ST is activated, the ready/busy signal generator 172 may output the ready/busy signal RB and notify the memory controller 1200 that the memory device 1100 is operating.

The CMD decoder 173 may select one of a plurality of ROM lines RL1 to RLn in response to the command code CMDC<n:1>, where n is a positive integer. In particular, the CMD decoder 173 may directly select a ROM line corresponding to the command code CMDC<n:1>, among the plurality of ROM lines RL1 to RLn, without searching for the ROM line by sequentially matching the received command code CMDC<n:1> with each one of the ROM lines RL1 to RLn. In various embodiments, the CMD decoder 173 may include a ROM table. In other words, when the command code CMDC<n:1> is input, the CMD decoder 173 may directly select a ROM line corresponding to the command code CMDC<n:1> by using the ROM table. For example, a ROM line selected from among the plurality of ROM lines RL1 to RLn may be enabled, and unselected ROM lines may be disabled.

The ROM code generator 174 may output a ROM code R_CODE# corresponding to the selected ROM line. By way of example, the ROM code generator 174 may be composed of a ROM storing ROM codes corresponding to various operations. Different ROM codes may be output in response to voltages applied to different ROM lines. Since the ROM code generator 174 is composed of a ROM, different ROM codes stored in the ROM cannot be modified. When the selected ROM line, among the ROM lines coupled to different ROMs, is enabled, the ROM code R_CODE# coupled to the enabled ROM line may be output.

The operation controller 175 may output the various operating signals OP_SIG and the page control signals PBSIG in response to the ROM code R_CODE#. In various embodiments, various algorithms for performing various operations may be stored in the operation controller 175. When the ROM code R_CODE# is received, the operation controller 175 may output the operating signals OP_SIG and the page control signals PBSIG in response to an algorithm corresponding to the ROM code R_CODE#. By way of example, an algorithm may include software for operating a reset operation, a CAM read operation, a normal read operation, a copyback read operation, a normal program operation, a copyback program operation, a cache program operation, a re-program operation, or a normal erase operation. According to the selected algorithm, the operation controller 175 may control the operating signals OP_SIG and the page control signals PBSIG.

When the address ADD is received from the memory controller 1200, the ADD decoder 176 may decode the received address ADD and output the row address RADD and the column address CADD.

FIG. 6 is a diagram illustrating a read only memory (ROM) table in accordance with an embodiment of the present disclosure, for example, the ROM table stored in the CMD decoder 173 of FIG. 5.

Referring to FIG. 6, the CMD decoder 173 may include the ROM table.

The ROM table may include a plurality of different command codes CMDC and descriptions (or operation information) Description mapped to each of the command codes CMDC. In other words, each of the command codes CMDC may include eight different bits, and different command codes CMDC may be mapped to different descriptions. One of the command codes CMDC may be input to the ROM table. One of the ROM lines may be selected from among the ROM lines RL in response to the description mapped to the input command code. The CMD decoder 173 may float unselected ROM lines or apply a disable signal thereto.

The command codes CMDC may be individually set to perform algorithms for various operations. For example, the command code CMDC ‘00000000’ may be a command code for performing a reset operation, and the first ROM line RL1 may be selected in response to the command code CMDC ‘00000000’. The command code CMDC ‘00000001’ may be a command code for performing a CAM read operation. The second ROM line RL2 may be selected in response to the command code CMDC ‘00000001’. The command code CMDC ‘00000010’ may be a command code for performing a normal read operation. The third ROM line RL3 may be selected in response to the command code CMDC ‘00000010’. The command code CMDC ‘00000011’ may be a command code for performing a copyback read operation. The fourth ROM line RL4 may be selected in response to the command code CMDC ‘00000011’. The command code CMDC ‘00000100’ may be a command code for performing a normal program (PGM) operation. The fifth ROM line RL5 may be selected in response to the command code CMDC ‘00000100’. The command code CMDC ‘00000101’ may be a command code for performing a copyback PGM operation. The sixth ROM line RL6 may be selected in response to the command code CMDC ‘00000101’. The command code CMDC ‘00000110’ may be a command code for performing a cache PGM operation. The seventh ROM line RL7 may be selected in response to the command code CMDC ‘00000110’. The command code CMDC ‘00000111’ may be a command code for performing a re-PGM operation. The eighth ROM line RL8 may be selected in response to the command code CMDC ‘00000111’. The command code CMDC ‘00001000’ may be a command code for performing a normal erase operation. The ninth ROM line RL9 may be selected in response to the command code CMDC ‘00001000’.

The descriptions executed by the above-described command codes CMDC may vary depending on memory devices. The command codes CMDC may be set for more various operations than those shown in FIG. 6. When one of the above-described command codes CMDC is input, the CMD decoder 173 may directly select a ROM line RL according to the ROM table and output an enable signal to the selected ROM line RL. Unselected ROM lines may be floated or a disable signal may be applied thereto. For example, when the command code CMDC ‘00000100’ is input, the CMD decoder 173 may directly output an enable signal to the fifth ROM line RL mapped to the command code CMDC ‘00000100’. As described above, since the ROM line RL corresponding to the input command code CMDC is directly selected, a command may be executed more quickly than the existing method by which all descriptions are sequentially searched. In other words, after a command is input, a selected operation may start quickly according to the input command.

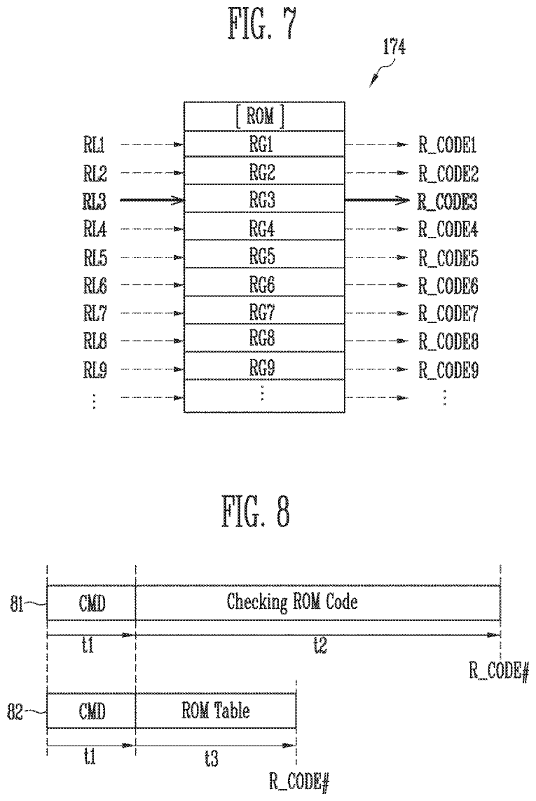

FIG. 7 is a diagram illustrating a read only memory (ROM) in accordance with an embodiment of the present disclosure, for example, the ROM included in the ROM code generator 174 of FIG. 5.

Referring to FIG. 7, the ROM code generator 174 may include a plurality of registers RG coupled to the plurality of ROM lines RL, respectively. By way of example, the ROM may include first to ninth registers RG1 to RG9. The first to ninth registers RG1 to RG9 may be configured as a read only memory (ROM) which performs only a read operation. However, the first to ninth registers RG1 to RG9 may include various storage components such as a non-volatile memory in addition to the ROM.

The first to ninth registers RG1 to RG9 may store different ROM codes R_CODE1 to R_CODE9, respectively. A corresponding ROM code R_CODE may be output from a corresponding register coupled to the ROM line RL to which an enable signal is applied. For example, when the enable signal is applied to the third ROM line RL3 and the first, second and fourth to ninth ROM lines RL1, RL2, and RL4 to RL9 may be floated or a disable signal is applied thereto, the third ROM code R_CODE3 stored in the third register RG3 may be directly output. When the third ROM code R_CODE3 is output, the operation controller 175 of FIG. 5 may execute a normal read operation corresponding to the third ROM code R_CODE3 (see FIG. 6). In other words, the operation controller 175 may control the operating signals OP_SIG and the page control signals PBSIG according to the normal read operation.

FIG. 8 is a diagram illustrating comparative examples of output times of ROM codes between the conventional art and an embodiment of the present invention.

Referring to FIG. 8, in the case of the conventional art (81), it may take a first time t1 for the memory controller 1200 of FIG. 1 to output the command CMD after receiving a request from the host 2000, and it may take a second time t2 for the memory device 1100 to output the ROM code R_CODE# after receiving the command CMD from the memory controller 1200. In the conventional art (81), during the second time t2, in order to find the ROM code R_CODE# corresponding to the received command CMD, the plurality of ROM codes may be sequentially checked. As a result, the second time t2 taken until the ROM code R_CODE# is output may be relatively prolonged.

In this embodiment (82) as described above, it may take the first time t1 until the memory controller 1200 outputs the command CMD in the same manner as the conventional art (81). However, it may take a third time t3 shorter than the second time t2 for the memory device 1100 to output the ROM code R_CODE# after receiving the command CMD from the memory controller 1200. In this embodiment (82), when the memory device 1100 receives the command CMD, the memory device 1100 may directly output the ROM code R_CODE# corresponding to the command CMD by using the ROM table. Therefore, the ROM code R_CODE# may be output in a shorter time than the conventional art (81) in which each of the commands CMD and each of the ROM codes R_CODE# are searched to match with each other in a sequential manner. A substantial operation corresponding to the command CMD in the memory device 1100 may be executed according to the ROM code R_CODE#. Therefore, an operation may start earlier as the ROM code R_CODE# is output faster.

Since the time taken until the memory device 1100 starts an operation after receiving the command CMD may be shortened, the entire operation time of the memory device 1100 may be shortened. Accordingly, the operation time of the memory system 1000 including the above-described memory device 1100 may be shortened.

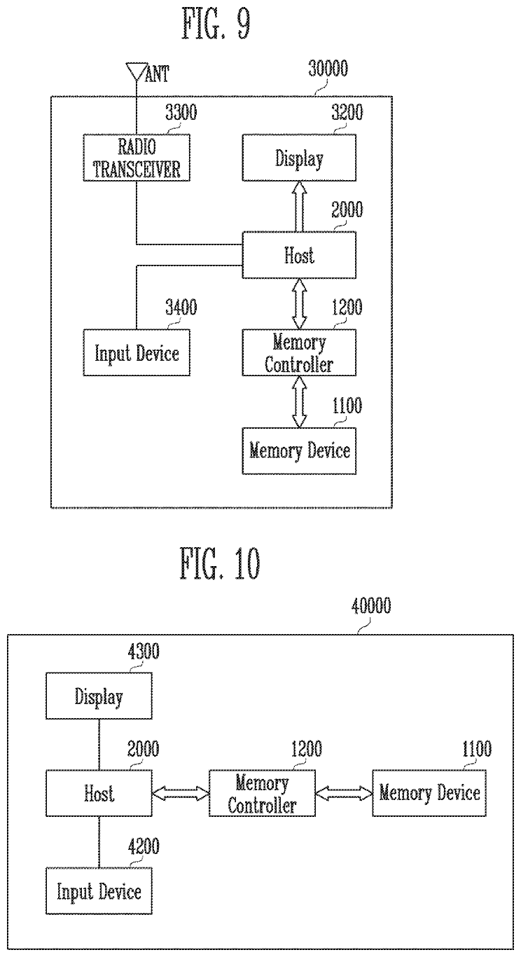

FIG. 9 is a diagram illustrating a memory system 30000 in accordance with an embodiment of the present disclosure.

Referring to FIG. 9, the memory system 30000 may be embodied into a cellular phone, a smart phone, a tablet personal computer (PC), a personal digital assistant (PDA), or a wireless communication device.

The memory system 30000 may include the memory device 1100, the memory controller 1200 controlling operations of the memory device 1100, and the host 2000 controlling the memory controller 1200. The memory controller 1200 may control a data access operation of the memory device 1100, for example, a program operation, an erase operation or a read operation of the memory device 1100 in response to control of the host 2000.

The memory controller 1200 may control data programmed into the memory device 1100 to be output through a display 3200 in response to control of the memory controller 1200.

A radio transceiver 3300 may exchange a radio signal through an antenna ANT. For example, the radio transceiver 3300 may change the radio signal received through the antenna ANT into a signal which can be processed by the host 2000. Therefore, the host 2000 may process the signal output from the radio transceiver 3300 and transfer the processed signal to the memory controller 1200 or the display 3200. The memory controller 1200 may transfer the signal processed by the host 2000 into the semiconductor memory device 1100. In addition, the radio transceiver 3300 may change a signal output from the host 2000 into a radio signal and output the radio signal to an external device through the antenna ANT. A control signal for controlling the operations of the host 2000 or data to be processed by the host 2000 may be input by an input device 3400. The input device 3400 may include a pointing device, such as a touch pad, a computer mouse, a keypad, or a keyboard. The host 2000 may control the operations of the display 3200 so that data output from the memory controller 1200, data output from the radio transceiver 3300, or data output from the input device 3400 may be output through the display 3200.

FIG. 10 is a diagram illustrating a memory system 40000 in accordance with an embodiment of the present disclosure.

Referring to FIG. 10, the memory system 40000 may be embodied into a personal computer (PC), a tablet PC, a net-book, an e-reader, a personal digital assistant (PDA), a portable multimedia player (PMP), an MP3 player, or an MP4 player.

The memory system 40000 may include the memory device 1100, the memory controller 1200 controlling data processing operations of the memory device 1100, and the host 2000 controlling the memory controller 1200.

In addition, the host 2000 may output the data stored in the memory device 1000 through a display 4300 according to the data input through an input device 4200. Examples of the input device 4200 may include a pointing device such as a touch pad, a computer mouse, a keypad, or a keyboard.

The host 2000 may control the general operations of the memory system 40000 and control the operations of the memory controller 1200.

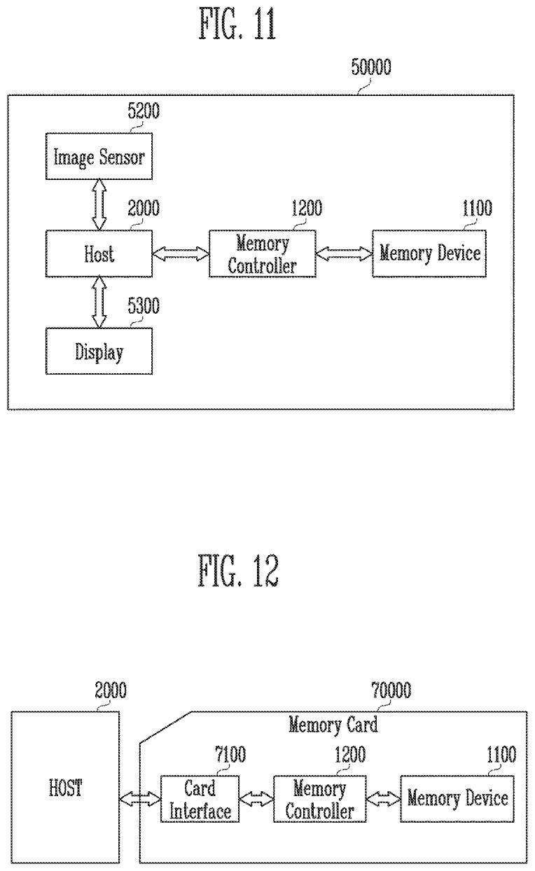

FIG. 11 is a diagram illustrating a memory system 50000 in accordance with an embodiment of the present disclosure.

Referring to FIG. 11, the memory system 50000 may be provided as an image processing device, for example, a digital camera, a mobile phone with a digital camera, a smart phone with a digital camera, or a tablet PC with a digital camera.

The memory system 50000 may include the memory device 1100, the memory controller 1200 controlling a data processing operation of the memory device 1100, for example, a program operation, an erase operation or a read operation, and the host 2000 controlling the memory controller 1200.

An image sensor 5200 may convert an optical image into digital signals, and the digital signals may be transferred to the host 2000. In response to control of the host 2000, the digital signals may be output through a display 5300 or stored in the memory device 1100 through the memory controller 1200. In addition, the data stored in the memory device 1100 may be output through the display 5300 according to control of the host 2000.

FIG. 12 is a diagram illustrating a memory card 70000 as an example of the memory system 1000 shown in FIG. 1 in accordance with an embodiment of the present disclosure.

Referring to FIG. 12, the memory card 70000 may be embodied into a smart card. The memory card 70000 may include the memory device 1100, the memory controller 1200 and a card interface 7100.

The memory controller 1200 may control data exchange between the memory device 1100 and the card interface 7100. In accordance with an embodiment, the card interface 7100 may be, but not limited thereto, a secure digital (SD) card interface or a multi-media card (MMC) interface. In addition, the card interface 7100 may interface data exchange between the host 2000 and the memory controller 1200 according to a protocol of the host 2000. In accordance with an embodiment, the card interface 7100 may support a Universal Serial Bus (USB) protocol and an InterChip (IC)-USB protocol. The card interface 7100 may refer to hardware that supports a protocol used by the host 2000, software mounted on the hardware, or a signal transmission method.

In accordance with the present disclosure, when a command is received from a memory controller, a ROM code corresponding to the received command may be directly selected, so that a time taken for a memory device to start an operation may be shortened.

While the exemplary embodiments of the present disclosure have been disclosed for illustrative purposes, those skilled in the art will appreciate that various modifications, additions and substitutions are possible. Thus, it is intended that the present invention cover all such modifications provided the modifications come within the scope of the appended claims and their equivalents.

What is claimed is:

1. A memory device, comprising:
a command encoder encoding a command into a command code;
a command decoder decoding the command code, selecting one of a plurality of read only memory (ROM) lines according to a decoding result, and outputting an enable signal through a selected ROM line among the plurality of ROM lines;
a ROM code generator including a plurality of registers storing ROM codes for executing various operations and outputting a ROM code stored in a register to which the enable signal is input, among the plurality of registers; and
an operation controller executing an algorithm according to the ROM code output from the ROM code generator.

2. The memory device of claim 1, wherein the command encoder encodes the command to output the command code comprising a plurality of bits.

3. The memory device of claim 1, wherein the command encoder varies and outputs the command code according to the command.

4. The memory device of claim 1, wherein the command decoder includes a ROM table in which the ROM lines are mapped to a plurality of different command codes, respectively.

5. The memory device of claim 4, wherein the command decoder outputs an enable signal to a ROM line mapped to the command code when the command code is input.

6. The memory device of claim 5, wherein the command decoder floats remaining ROM lines, except for the ROM line to which the enable signal is applied.

7. The memory device of claim 1, wherein the ROM code generator includes the registers coupled to the ROM lines, respectively, which store the ROM codes which are different from each other.

8. The memory device of claim 7, wherein the ROM code generator outputs the ROM code stored in the register to which the enable signal is input, among the registers.

9. The memory device of claim 7, wherein each of the registers comprises a read only memory (ROM) or a non-volatile memory.

10. The memory device of claim 1, wherein the operation controller controls operating signals and page control signals according to the algorithm executed by the ROM code output from the ROM code generator.

11. The memory device of claim 1, wherein the algorithm includes software for performing a reset operation, a CAM read operation, a normal read operation, a copyback read operation, a normal program operation, a copyback program operation, a cache program operation, a re-program operation, or a normal erase operation.

12. The memory device of claim 1, further comprising:
a plurality of memory blocks storing data;
a voltage generator generating various operating voltages in response to operating signals;
page buffers controlling voltages of bit lines in response to page control signals;
a row decoder transferring the operating voltages to a selected memory block, among the memory blocks, in response to a row address;
a column decoder exchanging data with the page buffers in response to a column address; and
an input and output circuit exchanging the command, an address, and the data with the memory controller.

13. The memory device of claim 12, further comprising an address decoder decoding the address received from the memory controller to output the row address and the column address.

14. The memory device of claim 1, wherein the command encoder outputs an operation start signal when outputting the command code.

15. The memory device of claim 14, further comprising a ready and busy signal generator outputting a ready/busy signal indicating that the memory device is operating in response to the operation start signal.

16. A method for operating a memory device, the method comprising:
receiving a command in response to a request of a host;
encoding the command into a command code comprising a plurality of bits;
outputting an enable signal to a read only memory (ROM) line mapped to the command code;
outputting a ROM code stored in a register to which the enable signal is input, among a plurality of registers; and
executing an algorithm according to the ROM code.

17. The method of claim 16, wherein the outputting of the enable signal comprises outputting the enable signal to the ROM line mapped to the command code by using a ROM table in which a plurality of ROM lines is mapped to a plurality of different command codes, respectively.

18. The method of claim 17, wherein the enable signal is directly applied to a selected ROM line, among the ROM lines, when the command code is output.

19. The method of claim 16, wherein different ROM codes are stored in the registers, and the ROM code stored in the register to which the enable signal is input, among the registers storing the different ROM codes, is directly output.

20. The method of claim 16, wherein operating signals and page control signals for controlling a peripheral circuit included in the memory device are output according to the algorithm.

21. The method of claim 20, wherein the algorithm includes software for controlling the operating signals and the page control signals according to a reset operation, a CAM read operation, a normal read operation, a copyback read operation, a normal program operation, a copyback program operation, a cache program operation, a re-program operation, or a normal erase operation.
